(19) United States
(12) Patent Application Publication
(10) Pub. No.: US 2009/0321842 A1
(43) Pub. Date: Dec. 31, 2009

(54) Method for manufacturing semiconductor device including metal gate electrode and semiconductor device

(75) Inventor: Yoshihisa Matsubara, Kanagawa (JP)

Correspondence Address: MCGINN INTELLECTUAL PROPERTY LAW GROUP, PLLC, 8321 OLD COURTHOUSE ROAD, SUITE 200, VIENNA, VA, 22182-3817, US

(73) Assignee: NEC ELECTRONICS CORPORATION, Kawasaki (JP)

(21) Appl. No.: 12/457,898

(22) Filed: Jun. 24, 2009

(30) Foreign Application Priority Data
Jun. 25, 2008 (JP) 2008-165678

(51) Int. Cl. H01L 27/092; H01L 21/28

(52) U.S. Cl. 257/369; 438/585; 438/199; 257/E27.062; 257/E21.19

(57) ABSTRACT

A first metal film mainly including Ta is formed on a gate insulating film in a region excluding an n MOS transistor formation region and then a polysilicon film is formed to cover the gate insulating film and the first metal film. A first dummy electrode is formed by selectively removing the gate insulating film and the polysilicon film by etching, and a second dummy gate is formed by selectively removing the gate insulating film, the first metal film and the polysilicon film. An insulating layer is formed to embed the dummy gate electrodes and to expose an upper surface of the dummy gate electrodes. The polysilicon film of the dummy gate electrodes is removed to form recesses in the insulating layer, then a second metal film is formed within the recesses and on the insulating layer, and the second metal film is selectively polished.

### INCORPORATION BY REFERENCE

The application is based upon and claims the benefit of priority from Japanese Patent Application No. 2008-165678 which was filed on Jun. 25, 2008, the disclosure of which is incorporated herein in its entirety by reference.

### BACKGROUND OF THE INVENTION

1. Field of the Invention

The present invention relates to a method for manufacturing a semiconductor device, and to a semiconductor device.

2. Description of Related Art

As a related art, semiconductor devices in which an n type MOSFET and a p type MOSFET are provided on the same semiconductor substrate have been used.

In such a semiconductor device, a threshold voltage value needs to be set in accordance with each MOSFET to have a value suitable for the MOSFET. To meet the need, methods have been proposed in which a metal material having a work function suitable for a gate electrode of each MOSFET is selected.

Japanese Patent Application Laid Open No. 2006-351580 discloses a gate insulating film 802, such as an HfSiON film, formed so as to cover an inner surface of grooves of an insulating layer 801 on a substrate 800, as shown in FIG. 4A. Subsequently, a first gate electrode material layer 803 made of Ta, Hf, Ti or the like is formed on the gate insulating film 802. Next, a mask layer 804 is formed, and as shown in FIGS. 4B and 4C, the first gate electrode material layer 803 inside the groove in which a gate of an n type MOS transistor is to be formed is removed. Then, as shown in FIG. 4D, the mask layer 804 is removed, and as shown in FIG. 4E, a second gate electrode material layer 805 is formed. The second gate electrode material layer 805 is made of a metal material to be used as a gate electrode material of the n type MOS transistor, which is Ti, Hf, Ta, W, or Ru. Next, as shown in FIG. 4F, the second gate electrode material layer 805 is selectively removed, and left only inside of the groove. Further, as shown in FIG. 4G, an inside of each groove is filled with an electrode metal 806.

That is, the gate insulating film 802, such as an HfSiON film, is formed inside the groove. Formation of the gate insulating film 802 inside the groove is performed by using a CVD system. However, a thickness of the gate insulating film 802 varies depending on embedding characteristics of the CVD system. Accordingly, there is a problem that a threshold of a transistor varies depending on the embedding characteristics of the CVD system.

For that reason, the threshold of the transistor cannot be set to a predetermined value, and therefore, the method has a problem of inferior stability in manufacturing the semiconductor device.

Japanese Patent Application Laid Open No. 2006-351978 and Japanese Patent Application Laid Open No. 2006-261190 also disclose a gate insulating film inside the groove.

2007 Symposium on VLSI Technology Digest of Technical Papers, pp. 196 to 197, Integration Friendly Dual Metal Gate Technology Using Dual Thickness Metal inserted Poly-Si stacks (DT-MIPS) discloses a semiconductor device including a pMOS gate electrode in which an HfON film, a TaN film, an AlOx film, a cap metal layer and a polysilicon are stacked sequentially from a substrate side, and an nMOS gate electrode in which an HfON film, a TaN film and polysilicon are stacked sequentially from the substrate side. In the semiconductor device, an HfON film, a TaN film, an AlOx film and a cap metal layer are stacked on a semiconductor substrate in a sheet form. Subsequently, the AlOx film and cap metal layer of the n MOS gate electrode are removed by etching. Next, polysilicon is stacked, and the stacked body is selectively removed by etching so as to obtain each gate electrode.

That is, the document uses the polysilicon as the gate electrode. Therefore, the document fails to disclose a second gate electrode material layer which includes a metal material to be used as a gate electrode material of the n type MOS transistor, which is Ti, Hf, Ta, W, or Ru.

### SUMMARY

A method for manufacturing a semiconductor device includes a first MOS transistor and a second MOS transistor of a conductivity type opposite to that of the first MOS transistor are formed on a same semiconductor substrate. The method includes providing a gate insulating film on the semiconductor substrate in a second MOS transistor formation region and a first MOS transistor formation region, and forming a first metal film mainly including Ti or Ta on the gate insulating film in a region excluding the first MOS transistor formation region and including the second MOS transistor formation region. A polysilicon film is formed so as to cover the gate insulating film and the first metal film. A first dummy gate electrode is formed by selectively removing the gate insulating film and the polysilicon film by etching, at a position at which a gate electrode for the first MOS transistor is to be formed, and a second dummy gate electrode is formed by selectively removing the gate insulating film, the first metal film, and the polysilicon film, at a position at which a gate electrode for the second MOS transistor is to be formed. The first dummy gate electrode and the second dummy gate electrode are embedded with an insulating layer, and the polysilicon film of each of the dummy gate electrodes are exposed from the insulating layer surface. The polysilicon film of the first dummy gate electrode and the polysilicon film of the second dummy gate electrode are removed to form recesses in the insulating layer and a second metal film is formed within the recesses and on the insulating layer, and removing the second metal film is removed on the insulating layer by polishing.

According to the exemplary aspect of the invention, the gate insulating film is formed on the semiconductor substrate, and subsequently the gate insulating film is selectively removed by etching. In the aspect of the present invention, the gate insulating film is formed not by forming the groove in the insulating layer, and subsequently embedding the inside of the groove as in the related art.

Accordingly, it is possible to prevent fluctuation of the thickness of the gate insulating film due to the embedding characteristics of the CVD system.

In the exemplary aspect of the present invention, the first dummy gate electrode is formed by selectively removing the gate insulating film and the polysilicon film by etching, at a position at which the gate electrode for the first MOS transistor is to be formed, and the second dummy gate electrode is formed by selectively removing the gate insulating film, the first metal film, and the polysilicon film, at a position at which the gate electrode for the second MOS transistor is to be formed.

Since the first metal film mainly includes Ti or Ta, the first metal film can be easily removed, for example, by etching. Accordingly, the second dummy gate electrode as well as the gate electrode for the second MOS transistor can be stably formed.

Moreover, the polysilicon film of the first dummy gate electrode and the polysilicon film of the second dummy gate electrode are removed to form the recesses in the insulating layer. Further, the second metal film is provided so as to cover the insulating layer and the recesses, and the second metal film on the insulating layer is removed by polishing.

For that reason, even when it is difficult to remove the second metal film by etching, the second metal film is removed by polishing. Thereby, the second metal film can be selectively removed with ease.

As described, the first metal film suitable for etching is removed by etching, and the second metal film is removed by polishing. A process method in accordance with the characteristics of each metal film is selected. Accordingly, it is possible to stably form the gate electrode for the first MOS transistor and the gate electrode for the second MOS transistor.

As mentioned above, a semiconductor device having excellent manufacture stability can be manufactured.

A semiconductor device as follows can be obtained with the above-mentioned manufacturing method.

A semiconductor device includes a first MOS transistor and a second MOS transistor of a conductivity type opposite to that of the first MOS transistor, which are formed on a same semiconductor substrate. In the semiconductor device, an insulating layer is provided on the semiconductor substrate, the first MOS transistor has a first gate electrode formed within the insulating layer. The first gate electrode has an approximately plate-like gate insulating film, and a metal film having a covering part for covering an approximately whole surface of the gate insulating film and a peripheral wall part provided upright on a periphery of the covering part. The second MOS transistor has a second gate electrode formed within the insulating layer; the second gate electrode has an approximately plate-like gate insulating film, an approximately plate-like metal film that is disposed on the gate insulating film so as to cover an approximately whole surface of the gate insulating film and mainly includes Ti or Ta, and a metal film having a covering part for covering an approximately whole surface of the metal film mainly composed of Ti or Ta and a peripheral wall part provided upright on a periphery of the covering part. An upper end portion of the peripheral wall part of the metal film of the first gate electrode and an upper end portion of the peripheral wall part of the metal film of the second gate electrode are approximately on a same plane as the surface of the insulating layer is. The metal film having the covering part and the peripheral wall part of the first gate electrode and the metal film having the covering part and the peripheral wall part of the second gate electrode are formed of a same material.

Since such a semiconductor device can be manufactured with the manufacturing method mentioned above, the semiconductor device has excellent stability in manufacture.

According to the exemplary aspect of the present invention, a semiconductor device having excellent manufacture stability and a method for manufacturing the semiconductor device are provided.

### BRIEF DESCRIPTION OF THE DRAWINGS

The above and other exemplary aspects, advantages and features of the present invention will be more apparent from the following description of certain exemplary embodiments taken in conjunction with the accompanying drawings, in which:

FIG. 1 illustrates a sectional view of a semiconductor device according to a first exemplary embodiment of the present invention;

FIGS. 2A to 2H illustrate sectional views showing a manufacturing process of the semiconductor device;

FIG. 3 is a sectional view showing a semiconductor device according to a second exemplary embodiment of the present invention; and

FIGS. 4A to 4G illustrate sectional views showing a manufacturing process of a semiconductor device of a related art.

### DETAILED DESCRIPTION OF THE EXEMPLARY EMBODIMENTS

### First Exemplary Embodiment

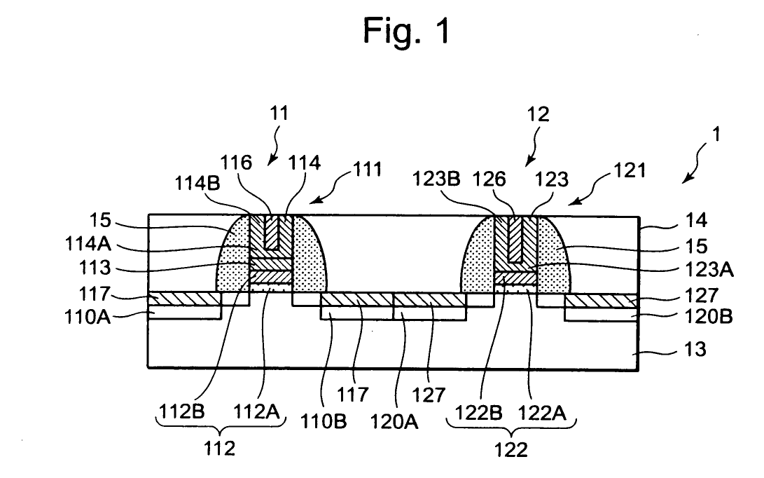

with reference to FIG. 1, description will be given on an outline of a semiconductor device 1 of the exemplary embodiment.

The semiconductor device 1 is a so-called CMOS device in which a p type MOS transistor (second MOS transistor) 11 and an n type MOS transistor (first MOS transistor) 12 are formed on a same semiconductor substrate 13. An insulating layer 14 is provided on the semiconductor substrate 13.

The n type MOS transistor 12 has a first gate electrode 121 formed within the insulating layer 14. The first gate electrode 121 includes an approximately plate-like gate insulating film 122 and a metal film 123 that has a covering part 123A for covering an approximately whole surface of the gate insulating film 122 and a peripheral wall part 123B provided upright on a periphery of the covering section 123A. The metal film 123 mainly includes one of metals of groups 6 to 8 in the periodic table and metals of groups 2 to 4 in the periodic table.

The p type MOS transistor 11 has a second gate electrode 111 formed within the insulating layer 14. The second gate electrode 111 includes an approximately plate-like gate insulating film 112; a metal film 113 that is disposed on the gate insulating film 112, has an approximately plate-like form to cover an approximately whole surface of the gate insulating film 112, and contains Titanium (Ti) or Tantalum (Ta), and a metal film 114 that has a covering part 114A for covering the approximately whole surface of the metal film 113 and a peripheral wall part 114B provided upright on a periphery of the covering part 114A. The metal film 114 mainly includes one of metals of groups 6 to 8 of the periodic table and metals of groups 2 to 4 of the periodic table.

An upper end portion of the peripheral wall part 123B of the metal film 123 containing the one of metals of groups 6 to 8 of the periodic table and metals of groups 2 to 4 of the periodic table in the first gate electrode 121, and an upper end portion of the peripheral wall part 114B of the metal film 114 containing the one of metals of groups 6 to 8 of the periodic table and metals of groups 2 to 4 of the periodic table in the second gate electrode 111 are on the approximately same plane as the surface of the insulating layer 14. The metal film 123 of the first gate electrode 121 and the metal film 114 of the second gate electrode 111 are formed of a same material.

Next, detailed description will be given on an outline of the semiconductor device 1.

The semiconductor substrate 13 is, for example, a silicon substrate. On the semiconductor substrate 13, the p type MOS transistor 11 and the n type MOS transistor 12 are provided. The n type MOS transistor 12 has a source region 120A, a drain region 120B, and the first gate electrode 121 that are formed on a surface layer of the semiconductor substrate 13. The source region 120A and the drain region 120B are disposed facing each other, with a region directly under the first gate electrode 121 interposed therebetween. In order to reduce a resistance of each region, an NiSi layer 127 is formed on each of an upper portion of the source region 120A and an upper portion of the drain region 120B.

The first gate electrode 121 is provided within the insulating layer 14, and a circumference of the first gate electrode 121 is surrounded by sidewall 15. Here, the insulating layer 14, although not shown, is a stacked body, for example, having an SiON film and an SiO₂ film provided on the SiON film. The first gate electrode 121 has the gate insulating film 122, the metal film 123, and a metal film 126. The gate insulating film 122 has an approximately plate-like form, and includes a plate-like SiO₂ film 122A that covers a surface of the semiconductor substrate 13 and a high dielectric constant film 122B provided on the SiO₂ film 122A.

The high dielectric constant film 122B has a dielectric constant higher than that of a silicon oxide film, and is the so-called high-k film of a dielectric constant not less than 10. As the high dielectric constant film 122B, Hafnium oxide nitrogen (HfON) film is preferable. The high dielectric constant film 122B also has an approximately plate-like form, and is disposed along a surface of the semiconductor substrate 13. Here, the approximately plate-like form refers to a state where a film is not provided upright on a periphery of a part that covers the semiconductor substrate surface along an inner surface of the sidewall 15.

The metal film 123 is a metal film for adjusting a threshold of an n type MOSFET, and mainly including or composed of, for example, one of metals of groups 6 to 8 of the periodic table and metals from groups 2 to 4 of the periodic table. Out of these metals, preferably, the metal film 123 mainly includes Chromium (Cr), Manganese (Mn), Molybdenum (Mo), Ruthenium (Ru), Tungsten (W), or one of metals of group 2 to 4 of the periodic table except Ti, for example, Lanthanum (La), Magnesium (Mg), etc. One of metals of groups 6 to 8 of the periodic table and metals of groups 2 to 4 of the periodic table, especially, Cr, Mn, Mo, Ru, W, or one of metals from groups 2 to 4 of the periodic table except Ti, for example, La, Mg, etc. is selected. Thereby, an effect of shifting threshold voltage (Vt) to a band edge is obtained. More preferably, the metal film 123 mainly includes La. Selection of La allows formation of the metal film 123 by the CVD method, and leads to an effect of easy control of a film thickness.

The metal film 123 is provided on the gate insulating film 122, and has the covering part 123A that covers the approximately whole surface of the gate insulating film 122 and the peripheral wall part 123B. In other words, the metal film 123 is formed to have an approximately U-shaped cross section. The upper end portion (end portion opposite to the covering part 123A of the peripheral wall part 123B and the surface of the insulating layer 14 are in a same level, and are flush with each other. Between the metal film 123 and the sidewall 15 and between the metal film 123 and the gate insulating film 122, a metal film for improving adhesion of the metal film 123 to the sidewall 15 (not shown), for example, a Tantalum nitride (TaN) film, is provided. A thickness of the TaN film is, for example, 10 nm, and a very thin film is formed. In the TaN film, the one of metals of groups 6 to 8 of the periodic table and metals of groups 2 to 4 of the periodic table that composes the metal film 123 is diffused. A metal nitride such as Titanium nitride (TiN) and Tungsten nitride (WN) films may be used instead of the TaN film. The TaN film as well as the metal film 123 has an approximately U shaped cross section.

Moreover, the metal film 126 is provided on the metal film 123. The metal film 126 is embedded into a recess inside the metal film 123. For example, the metal film 126 mainly includes W, and has a cross section of an approximately rectangular shape. The metal film 126 may be mainly composed of Aluminum (Al) or Copper (Cu). By using Al, deterioration of driving capability of the transistor can be suppressed.

The p type MOS transistor 11 has a source region 110A, a drain region 110B, and the second gate electrode 111 that are formed on the semiconductor substrate 13. The source region 110A and the drain region 110B are disposed facing each other, with a region directly under the second gate electrode 111 interposed therebetween. In order to reduce a resistance of each region, an Nickel Siliside (NiSi) layer 117 is formed on each of an upper portion of the source region 110A and an upper portion of the drain region 110B.

The second gate electrode 111 is provided within the insulating layer 14. Moreover, the circumference of the second gate electrode 111 is surrounded by the sidewall 15. The second gate electrode 111 is a stacked body of the gate insulating film 112, the metal film 113, metal film 114 and a metal film 116.

The gate insulating film 112 has an approximately plate-like form, and is formed flatly with an approximately uniform thickness. The gate insulating film 112 includes an SiO₂ film 112A of an approximately plate-like form that covers the surface of the semiconductor substrate 13 and a high dielectric constant film 112B provided on the SiO₂ film 112A. The high dielectric constant film 112B has a dielectric constant higher than that of a silicon oxide film, and is a so-called high-k film having a dielectric constant not less than 10, for example, an HfON film. The high dielectric constant film 112B also has an approximately plate-like form. The gate insulating film 11.2 is also formed of the same material as that of the gate insulating film 122.

The metal film 113 is a metal film for adjusting a work function of a gate electrode of a p type MOSFET, and is a film mainly including Ti or Ta. The metal film 113 preferably contains Ti. Selection of Ti provides an effect of secure etching. In addition, since Ti is used for wiring, there is an advantage that an apparatus used for a wiring process can be used. Moreover, it is particularly preferable that the metal film 113 is a TiN film. Moreover, more preferably, the metal film 113 is a TiN film to which Al is added. Use of the Al-added TiN film brings a Vt threshold to the band edge, and reduces Vt fluctuation with respect to an effective gate insulating film thickness (Eot). Thereby, the threshold of the p type MOS transistor 11 can be set to an optimal value. The metal film 113 is provided so as to approximately completely cover the gate insulating film 112, and the metal film 113 is also formed into an approximately plate-like form.

The metal film 114 has a covering part 114A for covering an approximately whole surface of the metal film 113 and a peripheral wall part 114B provided upright on a periphery of the covering part 114A. In other words, the metal film 114 is formed to have an approximately U-shaped cross section. An upper end portion (end portion opposite to the covering part 114A) of the peripheral wall part 114B and the surface of the insulating layer 14 are in a same level, and are flush with each other. The metal film 114 mainly includes one of metals of groups 6 to 8 of the periodic table and metals of groups 2 to 4 of the periodic table. Preferably, the metal film 114 includes Cr, Mn, Mo, Ru, W, or one of metals of group 2 to 4 of the periodic table except Ti, for example, La, Mg, etc. Especially, it is preferable to be composed of La. The metal film 114 and the metal film 123 are formed of a same material. Between the metal film 114 and the sidewalls 15 and between the metal film 114 and the metal film 113, a metal film (not shown, TaN film) for improving adhesion of the metal film 114 to the sidewalls 15 is provided. A thickness of the TaN film is 10 nm, for example. In the TaN film, the one of metals of groups 6 to 8 of the periodic table and metals of groups 2 to 4 of the periodic table in metal film 114 is diffused.

The metal film 116 is provided on the metal film 114. The metal film 116 is embedded into a recess inside the metal film 114. For example, the metal film 116 contains W and has a cross section of an approximately rectangular shape. The metal film 116 is formed of a same material as that of the metal film 126.

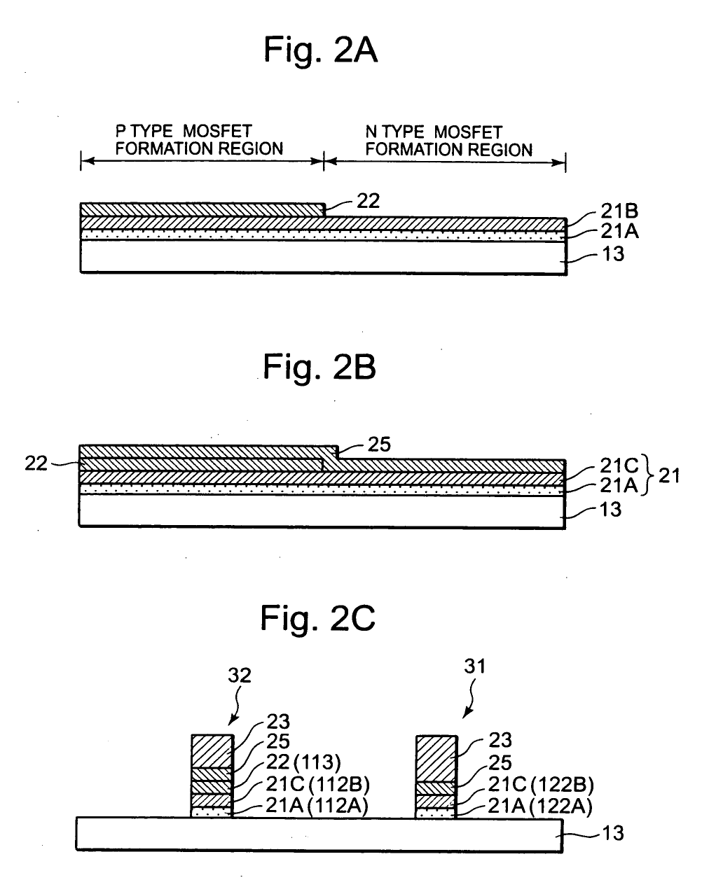

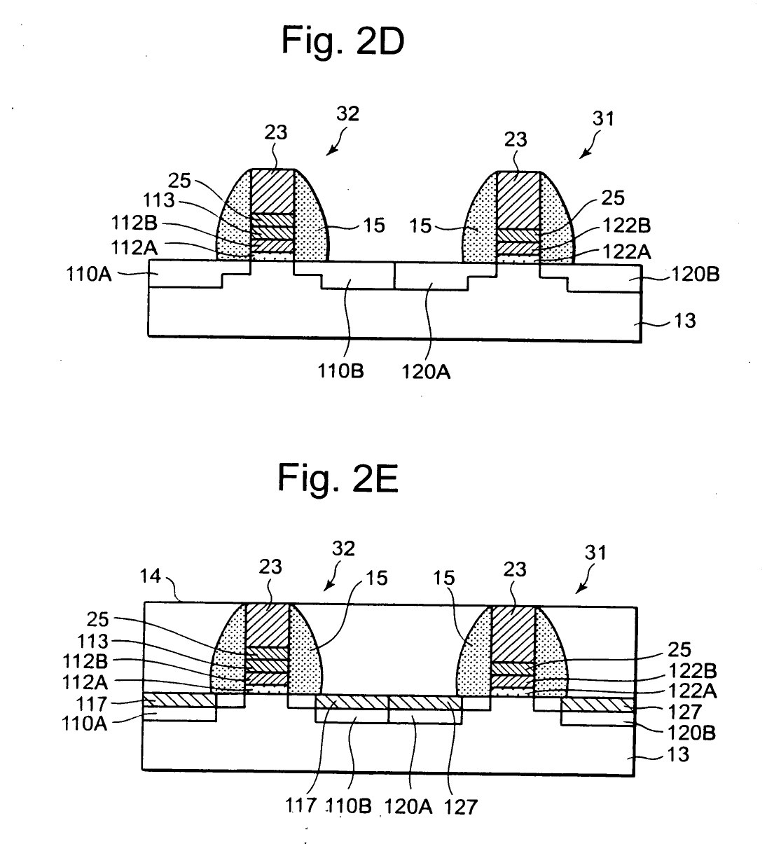

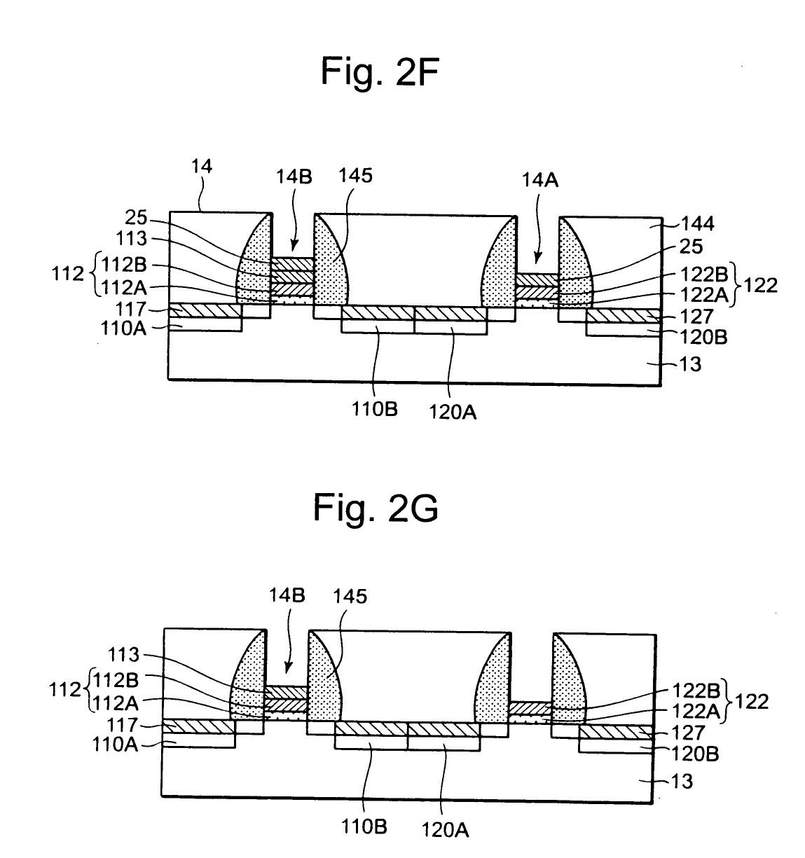

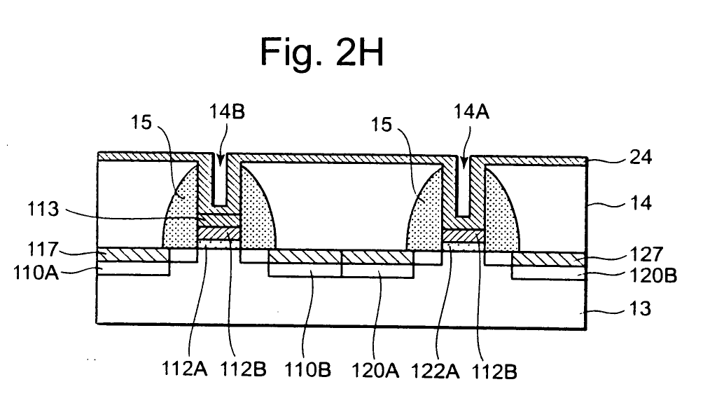

Next, with reference to FIGS. 2A to 2H, a method of manufacturing the semiconductor device 1 will be described.

First, description will be given on an outline of the method for manufacturing the semiconductor device 1.

The method of manufacturing the semiconductor device 1 of the exemplary embodiment includes: providing a gate insulating film 21 on the semiconductor substrate 13 in a p type MOS transistor formation region and n type MOS transistor formation region; forming a first metal film 22 mainly composed of Ti or Ta on the gate insulating film 21 in a region excluding the n type MOS transistor formation region and including the p type MOS transistor formation region; forming a polysilicon film 23 so as to cover the gate insulating film 21 and the first metal film 22; forming the first dummy gate electrode 31, by selectively removing the gate insulating film 21 and the polysilicon film 23 by etching, at a position at which a gate electrode for the n type MOS transistor is to be formed, and forming the second dummy gate electrode 32, by selectively removing the gate insulating film 21, the first metal film 22, and the polysilicon film 23, at a position at which a gate electrode for the p type MOS transistor is to be formed; providing an insulating layer 14 so that the first dummy gate electrode 31 and second dummy gate electrode 32 are embedded therein while each upper portion of the dummy gate electrodes 31 and 32 is exposed; removing the polysilicon film 23 of the first dummy gate electrode 31 and the polysilicon film 23 of the second dummy gate electrode 32 to form recesses 14A and 14B in the insulating layer 14; a step of providing a second metal film 24 within the recesses 14A and 14B and on the insulating layer 14, the second metal film 24 mainly composed of one of metals of groups 6 to 8 of the periodic table and metals of groups 2 to 4 of the periodic table; and selectively removing the second metal film 24 on the insulating layer 14 by polishing.

Next, detailed description will be given on the method for manufacturing the semiconductor device 1.

As shown in FIG. 2A, the surface of the semiconductor substrate 13 is oxidized and a SiO₂ film 21A is formed. The SiO₂ film 21A is to be a SiO₂ film 122A of the gate insulating film 122 of the first gate electrode 121 and a SiO₂ film 112A of the gate insulating film 112 of the second gate electrode 111. On the SiO₂ film 21 A, an HfO₂ film 21B covering the whole surface of the SiO₂ film 21A is formed. The SiO₂ film 21 A and the HfO₂ film 21 B are formed in a region including the p type MOS transistor formation region and the n type MOS transistor formation region, and cover these regions. Subsequently, the first metal film 22 is formed on the HfO₂ film 21B. The first metal film 22 covers the p type MOS transistor formation region of the HfO₂ film 21B, and does not cover the n type MOS transistor formation region. Here, the first metal film 22 is to be the metal film 113 of the gate electrode 111 of the p type MOS transistor 11. The first metal film 22 mainly includes Ti or Ta. Preferably, the first metal film 22 is a TiN film. More preferably, the first metal film 22 is a TiN film to which Al is added. In the case of adding Al, a target plate of TiAl can be used and an Al-added TiN film can be formed by sputtering.

Next, a stacked body including the SiO₂ film 21A, the HfO₂ film 21B and the first metal film 22 on the semiconductor substrate 13 is nitrided. For example, the stacked body is nitrided by ammonia plasma treatment, etc. The step turns the HfO₂ film 21B into an HfON film 21C (see FIG. 2B), and the first metal film 22 is hardened by being nitrided. The HfON film 21C becomes the high dielectric constant film 122B of the gate insulating film 122 of the first gate electrode 121 and the high dielectric constant film 112B of the gate insulating film 112 of the second gate electrode 111.

As shown in FIG. 2B, a third metal film 25 for covering the whole surfaces of the first metal film 22 and the HfON film 21C is formed on the first metal film 22 and the HfON film 21C. The third metal film 25 is formed in a region including the p type MOS transistor formation region and the n type MOS transistor formation region on the semiconductor substrate 13, and covers these areas. The third metal film 25 is a film mainly composed of Ti or Ta, and preferably, mainly includes the same metal as that of the first metal film 22. Preferably, the third metal film 25 is a TiN film, for example. The third metal film 25 can be formed, for example, by sputtering.

Subsequently, although not shown, a polysilicon film that covers an approximately whole surface of the third metal film 25 is provided on the third metal film 25. The polysilicon film is formed in a region including the p type MOS transistor formation region and the n type MOS transistor formation region to cover these regions.

As shown in FIG. 2C, the first dummy gate electrode 31 and the second dummy gate electrode 32 are formed. Specifically, the gate insulating film 21, the third metal film 25 and the polysilicon film are selectively removed by wet etching to form the first dummy gate electrode 31 at the position where the gate electrode 121 for the n type MOS transistor is to be formed. The first dummy gate electrode 31 is a stacked body of the gate insulating film 21 (21A, 21C), the third metal film 25 and the polysilicon film 23. Moreover, the gate insulating film 21, the first metal film 22, the third metal film 25 and the polysilicon film 23 are selectively removed by wet etching to form the second dummy gate electrode 32 at the position where the gate electrode 111 for the p type MOS transistor is to be formed. The second dummy gate electrode 32 is a stacked body of the gate insulating film 21 (21A, 21C), the first metal film 22 (metal film 113), the third metal film 25 and the polysilicon film 23.

Subsequently, impurity ions are injected into a surface layer of the semiconductor substrate 13 to form a source region and a drain region. Thereafter, sidewalls 15 adjacent to the dummy gate electrodes 31 and 32 are formed, respectively, and impurity ions are injected by using the sidewalls 15 as a mask. Thereby, as shown in FIG. 2D, the source regions 110A and 120A and the drain regions 110B and 120B are completed.

As shown in FIG. 2E, NiSi layers 117 and 127 are formed. Further, the insulating layer 14 that covers and completely embeds the dummy gate electrodes 31 and 32 and the sidewalls 15 is formed. Subsequently, the insulating layer 14 is polished to expose upper portions of the respective dummy gate electrodes 31 and 32 from the surface of the insulating layer 14.

As shown in FIG. 2F, the polysilicon film 23 of the first dummy gate electrode 31 and the polysilicon film 23 of the second dummy gate electrode 32 are removed, and the recesses 14A and 14B are formed in the insulating layer 14. Here, the polysilicon film 23 is removed by wet etching. As an etchant, for example, a polysilicon etching solution, specifically, fluoro nitric acid iodine containing glacial acetic acid, etc. can be used. At the time, the third metal film 25 is used as an etching stopper film. The polysilicon film 23 may be etched by dry etching.

As shown in FIG. 2G, the third metal film 25 is removed by wet etching. At the time, H₂O₂ and the like can be used as an etchant. By removing the third metal film 25, the gate insulating film 122 is left exposed in the first dummy gate electrode 31. On the other hand, in the second dummy gate electrode 32, the gate insulating film 112 and the metal film 113 provided on the gate insulating film 112 remain, so that the metal film 113 is exposed. Next, a TaN film is formed with atomic layer deposition so as to cover bottoms and sidewalls of the recesses 14A and 14B. The TaN film covers the gate insulating film 122 and the sidewall of the recess 14A in the first dummy gate electrode 31. The TaN film also covers the metal film 113 and the sidewall of the recess 14B in the second dummy gate electrode 32.

As shown in FIG. 2H, the second metal film 24 that is to be the metal films 114 and 123 is provided on the TaN film and the insulating film 14. The second metal film 24 becomes the metal films 114 and 123, and mainly includes one of metals of groups 6 to 8 of the periodic table and metals of groups 2 to 4 of the periodic table. Then, the second metal film 24 on the insulating layer 14 is removed by polishing. Specifically, the second metal film 24 on the insulating layer 14 is selectively removed by CMP. Thereby, the metal films 114 and 123 are formed. Next, the metal film 116 and the metal film 126 are respectively provided on the metal film 114 and the metal film 123. Specifically, a metal film that forms the metal film 116 and the metal film 126 is formed so as to embed cavity parts within the metal films 114 and 123 while being provided so as to cover the surface of the insulating layer 14. Subsequently, the metal film on the insulating layer 14 is selectively removed. Thereby, the metal film 116 and the metal film 126 are completed.

The semiconductor device 1 is obtained with the above-mentioned process. The above-mentioned semiconductor device 1 has excellent stability in manufacture.

Next, operation effects of the exemplary embodiment will be described.

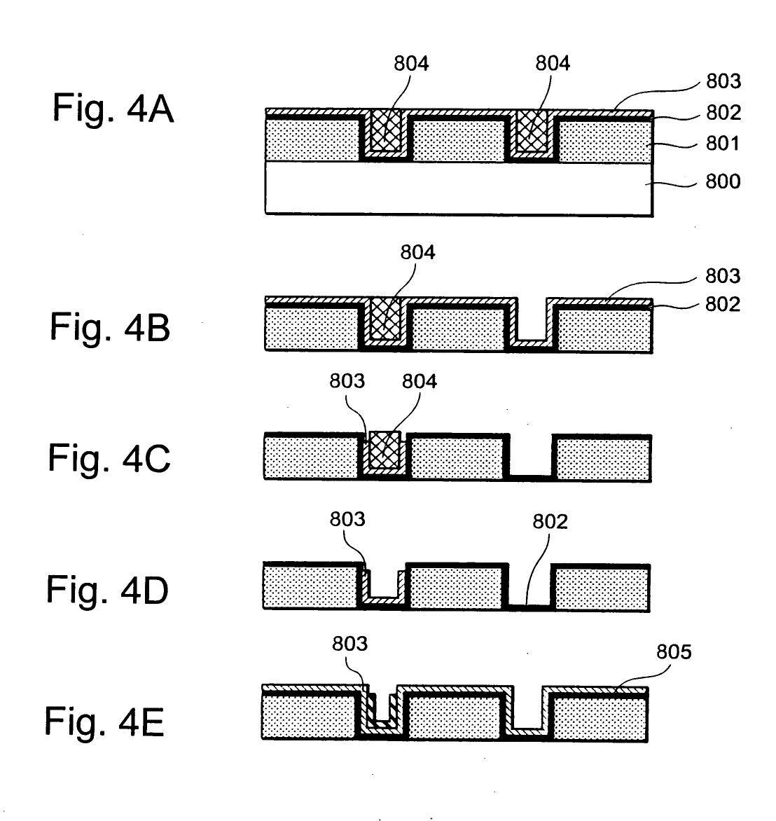

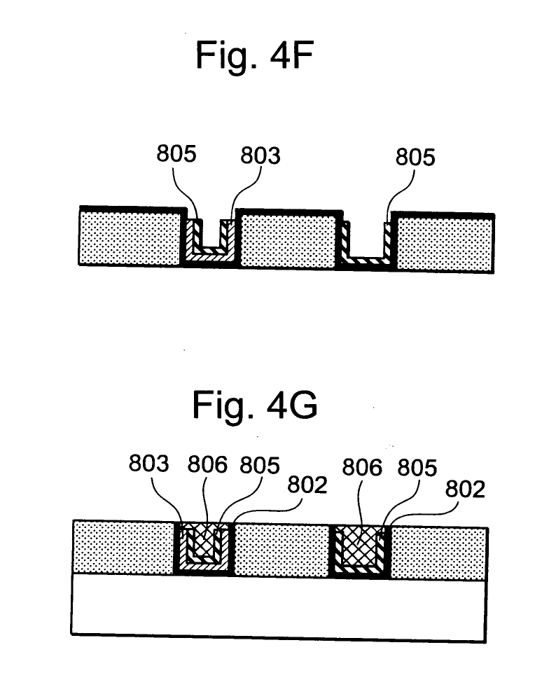

In the exemplary embodiment, the gate insulating film 21 is formed on the semiconductor substrate 13, and subsequently, the gate insulating film 21 is selectively removed by etching (FIG. 2B). In the exemplary embodiment, the gate insulating film is not formed by forming the groove in the insulating layer, and subsequently embedding the film inside the groove as in the related art (FIG. 4A). Accordingly, unlike in the related art, fluctuation in the thickness of the gate insulating film in accordance with the embedding characteristics of the CVD system can be prevented. Thereby, compared with the conventional manufacturing method described in Patent Document 1, the threshold of each transistor can be securely set to a desired value.

Moreover, in the exemplary embodiment, the first dummy gate electrode 31 is formed by selectively removing the gate insulating film 21, the third metal film 25 and the polysilicon film 23, at a position at which the gate electrode for the n type MOS transistor is to be formed, and the second dummy gate electrode 32 is formed by selectively removing the gate insulating film 21, the first metal film 22, the third metal film 22 and the polysilicon film, at a position at which the gate electrode for the p type MOS transistor is to be formed (FIG. 2C). Since the first metal film 22 and third metal film 25 mainly include Ti or Ta, the first metal film 22 and third metal film 25 can be easily removed by etching. Accordingly, the first dummy gate electrode and the second dummy gate electrode, as well as the gate electrode for the n type MOS transistor and the gate electrode for the p type MOS transistor can be formed stably.

Furthermore, in the exemplary embodiment, the polysilicon film 23 of the first dummy gate electrode 31 and the polysilicon film 23 of the second dummy gate electrode 32 are removed, and the recesses 14A and 14B are formed in the insulating layer 14 (FIG. 2G). Subsequently, the second metal film 24 mainly composed of one of metals of groups 6 to 8 of the periodic table and metals of the groups 2 to 4 of the periodic table is provided so as to cover the surface of the insulating layer 14 and the recesses 14A and 14B. Thereafter, the second metal film 24 on the insulating layer 14 is removed by polishing (FIG. 2H, FIG. 1).

The above-mentioned second metal film 24 is difficult to remove by etching. However, in the exemplary embodiment, since the second metal film 24 is removed by polishing, selective removal of the second metal film 24 can be easily performed. Particularly in a case of an alloyed second metal film 24, metal strength improves compared to a case of a simple metal, so that there is a tendency for etching to become difficult. However, in the exemplary embodiment, since the second metal film 24 is removed by polishing. Thus, even when the second metal film 24 is alloyed, the problem of difficulties in processing can be eliminated.

Moreover, in the exemplary embodiment, at a preceding stage of the step of forming the polysilicon film, the third metal film 25 containing Ti or Ta is formed in the p type MOS transistor formation region and the n type MOS transistor formation region (FIG. 2B). Then, the polysilicon film 23 is removed by etching while using the third metal film 25 as an etching stopper film (FIG. 2F). This allows suppression of damages to the gate insulating films 122 and 112, which are in a layer lower than the third metal film 25, when the polysilicon film 23 is removed.

Furthermore, in the exemplary embodiment, the first metal film 22 and the third metal film 25 are mainly composed of the same metal (FIG. 2B). This allows suppression of a difference in an etching rate when the first dummy gate electrode 31 and the second dummy gate electrode 32 are formed by etching.

Moreover, a large selection ratio of the gate insulating films 112 and 122 to the high dielectric constant films 112B and 122B can be achieved by using the TiN film as the third metal film 25 that is the etching stopper film. When a nitrided high dielectric constant film (especially, an HfON film) is used as the high dielectric constant films 112B and 122B, even larger selection ratio of the third metal film to the high dielectric constant film can be achieved. This can suppress etching of the high dielectric constant films 112B and 122B when the third metal film 25 that is the etching stopper film is removed.

Moreover, in the exemplary embodiment, the gate insulating film 21 and the first metal film 22 are stacked on the semiconductor substrate 13, and subsequently nitriding treatment is performed. The can turn the HfO₂ film 21B of the gate insulating film 21 into the HfON film 21C, and can make the first metal film 22 a relatively hard film. Since the third metal film 25 subsequently formed on the first metal film 22 is not subjected to the nitriding treatment step, the third metal film 25 is a softer film compared to the first metal film 22. Accordingly, when the third metal film 25 is removed from the second dummy gate electrode 32 by etching, only the third metal film 25 can be removed by etching, and the first metal film 22 can be left in the second dummy gate electrode 32.

Further, in the exemplary embodiment, at a preceding stage where the second metal film 24 is formed, the TaN film is provided in the recesses 14A and 14B. The TaN film covers the bottoms and sidewalls of the recesses 14A and 14B. By providing the second metal film 24 on the above-mentioned TaN film, adhesion of the second metal film 24 to the recesses 14A and 14B can be improved.

### Second Exemplary Embodiment

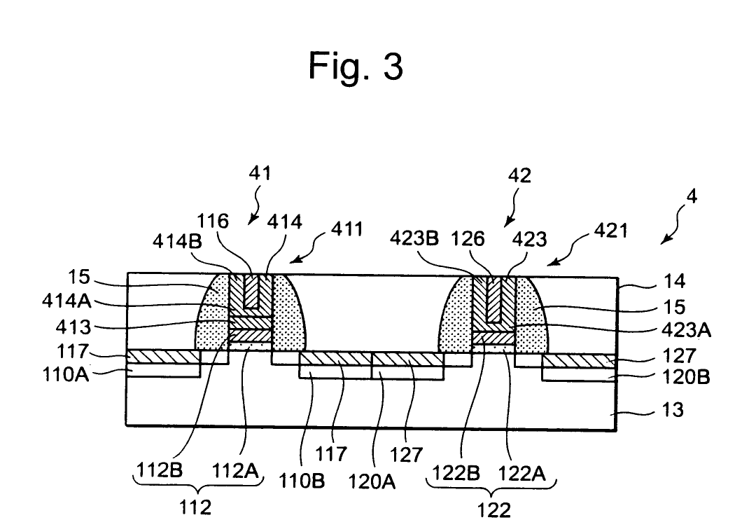

FIG. 3 illustrates a semiconductor device according to a second exemplary embodiment of the present invention.

A semiconductor device 4 of the exemplary embodiment is a so-called CMOS device in which an n type MOS transistor (second MOS transistor) 41 and a p type MOS transistor (first MOS transistor) 42 are formed on a same semiconductor substrate 13.

The p type MOS transistor 42 has a first gate electrode 421 formed within an insulating layer 14. The first gate electrode 421 includes: an approximately plate-like gate insulating film 122 a metal film 423 having a covering part 423A for covering an approximately whole surface of the gate insulating film 122 and a peripheral wall part 423B provided upright on a periphery of the covering part 423A, the metal film 423 containing one of metals of groups 6 to 8 of the periodic table and metals of groups 2 to 4 of the periodic table; and a metal film 126. Here, the metal film 423 is a metal film mainly including Ru, for example. Moreover, Al may be added to the metal film 423. Al in the metal film 423 is diffused in the gate insulating film 122. Thereby, the p type MOS transistor 42 with Vt controlled to be a desired value can be made.

The n type MOS transistor 41 has a second gate electrode 411 formed within the insulating layer 14. The second gate electrode 411 includes an approximately plate-like gate insulating film 112, an approximately plate-like metal film 413 disposed on the gate insulating film 112 so as to cover an approximately whole surface of the gate insulating film 112, the metal film 413 containing Ti or Ta, a metal film 414 having a covering part 414A for covering an approximately whole surface of the metal film 413 and a peripheral wall part 414B provided upright on a periphery of the covering part 414A, the metal film 414 containing one of metals of groups 6 to 8 of the periodic table and metals of the groups 2 to 4 of the periodic table, and a metal film 116.

The metal film 414 is formed of a same material as that of the metal film 423. Moreover, it is preferable that the metal film 413 is a TiN film, and is further preferable that a TiN film is added with La. An upper end portion of the peripheral wall part 423B of the metal film 423 containing one of metals of groups 6 to 8 of the periodic table and metals of groups 2 to 4 of the periodic table in the first gate electrode 421 and an upper end portion of the peripheral wall part 414B of the metal film 414 containing one of metals of groups 6 to 8 of the periodic table and metals of the groups 2 to 4 of the periodic table in the second gate electrode 411 are on the approximately same plane as the surface of the insulating layer 14.

The above-mentioned semiconductor device 4 can be manufactured with the same method as that of the first exemplary embodiment. Preferably, a TiN film to which La is added is used as the first metal film. Use of the La-added TiN film brings a Vt threshold to the band edge, and reduces Vt fluctuation with respect to an effective gate insulating film thickness (Eot). Thereby, the threshold of the n type MOS transistor can be set to an optimal value. Additionally, the first metal film covers only an n type MOS transistor formation region, and does not cover a p type MOS transistor formation region of an HfO₂ film. Moreover, as the second metal film, a metal film mainly includes, for example, one of metals of groups 6 to 8 of the periodic table, especially Ru, may be used.

The second exemplary embodiment can obtain the same effects as those in the first exemplary embodiment. In addition, the second exemplary embodiment can father obtain the below effects.

A metal film mainly including TiN is used as the metal film 413 that covers the gate insulating film 112 of the n type MOS transistor 41. Since Ti is used for wiring in many cases, when the metal film 413 mainly includes TiN, an apparatus used for wiring process can be used, and thereby manufacturing costs can be reduced. Use of the La-added TiN film for the metal film 413 brings a Vt threshold to the band edge, and reduces Vt fluctuation with respect to an effective gate insulating film thickness (Eot). Thereby, the threshold of the n type MOS transistor 41 can be set to an optimal value.

Note that the present invention is not limited to the above-mentioned exemplary embodiments. The present invention includes modifications, improvements, etc. within the scope that the objects of the present invention are achieved.

For example, in the first exemplary embodiment, the third metal film 25 that covers both of the p type MOS transistor formation region and the n type MOS transistor formation region is formed on the first metal film 22 formed in the region excluding the n type MOS transistor formation region. However, the present invention is not limited to the embodiment.

A metal film mainly including Ti or Ta may be formed on the gate insulating film to cover both of the p type MOS transistor formation region and the n type MOS transistor formation region, and subsequently, a metal film mainly including Ti or Ta may be formed in the region excluding the n type MOS transistor formation region. In the case, both of the metal films function as an etching stopper film when the polysilicon film is removed. Further, the first metal film 22 and the third metal film 25 mainly include the same metal in each of the exemplary embodiments. However, the present invention is not limited to the embodiment. The first metal film and third metal film each may be mainly composed of a different metal.

Moreover, although the TaN film is provided within the recesses in each of the exemplary embodiments, the TaN film may be unnecessary. The can facilitate the manufacturing process of the semiconductor device. Further, although the first metal film is the TiN film in each of the exemplary embodiments, the present invention is not limited to the embodiment. The first metal film may be a TiC film, for example. Since the TiC film does not easily oxidize compared with the TiN film, the threshold of the transistor can be more securely set to a value desired.

Moreover, in each of the exemplary embodiments, the second metal film mainly includes one of metals of groups 6 to 8 of the periodic table and metals of groups 2 to 4 of the periodic table. However, the second metal film is not limited to the embodiment.

Further, it is noted that Applicant's intent is to encompass equivalents of all claim elements, even if amended later during prosecution.

What is claimed is:

1. A method of manufacturing a semiconductor device in which a first MOS transistor and a second MOS transistor of a conductivity type opposite to that of the first MOS transistor are formed on a semiconductor substrate, the method comprising:
providing a gate insulating film on the semiconductor substrate in a second MOS transistor formation region and a first MOS transistor formation region;
forming a first metal film mainly including Ti or Ta on the gate insulating film in a region including the second MOS transistor formation region and excluding the first MOS transistor formation region;
forming a polysilicon film to cover the gate insulating film and the first metal film;
forming a first dummy gate electrode, by selectively removing the gate insulating film and the polysilicon film by etching, at a position at which a gate electrode of the first MOS transistor is to be formed, and forming a second dummy gate electrode, by selectively removing the gate insulating film, the first metal film, and the polysilicon film, at a position at which a gate electrode of the second MOS transistor is to be formed;
embedding the first dummy gate electrode and the second dummy gate electrode with an insulating layer, and subsequently exposing the polysilicon film of each of the dummy gate electrodes from a surface of the insulating layer;
removing the polysilicon film of the first dummy gate electrode and the polysilicon film of the second dummy gate electrode to form recesses in the insulating layer;
providing a second metal film within the recesses and on the insulating layer; and
selectively removing the second metal film on the insulating layer by polishing.

2. The method according to claim 1, wherein
the second metal film mainly includes one of metals of groups 6 to 8 of the periodic table and metals of the groups 2 to 4 of the periodic table.

3. The method according to claim 1, further comprising:
before forming the polysilicon film, forming a third metal film mainly including Ti or Ta in the second MOS transistor formation region and the first MOS transistor formation region so as to cover the first metal film,
wherein the recesses are formed by removing the polysilicon film by etching using the third metal film as an etching stopper film, and then, removing the third metal film.

4. The method according to claim 3, wherein
the gate insulating film includes a high dielectric constant gate insulating film containing Hf, and
after forming the first metal film, the first metal film and the gate insulating film are nitrided, and subsequently, the third metal film is formed.

5. The method according to claim 4, wherein
the first metal film and the third metal film mainly include Ti.

6. The method according to claim 5, wherein
the first MOS transistor includes an n type MOS transistor and the second MOS transistor includes a p type MOS transistor, and
the first metal film includes Al.

7. The method according to claim 5, wherein
the first MOS transistor includes a p type MOS transistor and the second MOS transistor includes an n type MOS transistor, and
the first metal film includes La.

8. The method according to claim 1, wherein
the second metal film within each of the recesses has an approximately U-shaped cross section so as to cover a bottom and a sidewall of the each recess, and
after removing the second metal film by polishing, an inside of the second metal film is filled with a metal film.

9. The method according to claim 1, wherein
the gate insulating film is provided on a flat surface of the semiconductor substrate at least extending through from the first MOS transistor formation region to the second MOS transistor formation region.

10. The method according to claim 1, wherein
the gate insulating film has a substantially uniform thickness.

11. A semiconductor device, comprising:
a first MOS transistor of a first conductivity type including a first gate electrode formed on a semiconductor substrate, the first gate electrode comprising:
a first approximately plate-like gate insulating film; and
a first metal film having a first covering part covering an approximately whole surface of the gate insulating film and a first peripheral wall part provided upright on a periphery of the first covering part;
a second MOS transistor of a second conductivity type including a second gate electrode formed on the semiconductor substrate, the second gate electrode comprising:
a second approximately plate-like gate insulating film;
a second metal film that has an approximately plate shape and is disposed on the gate insulating film so as to cover an approximately whole surface of the gate insulating film, and mainly includes Ti or Ta; and
a third metal film having a second covering part covering an approximately whole surface of the second metal film and a second peripheral wall part provided upright on a periphery of the second covering part;
an insulating layer covering the first and second MOS transistors, a top surface of the insulating layer being approximately on an upper end portion of the first peripheral wall part of the first metal film and an upper end portion of the second peripheral wall part of the third metal film, and
wherein the first metal film having the first covering part and the first peripheral wall part, and the third metal film having the second covering part and the second peripheral wall part are constituted by a same material.

12. The semiconductor device according to claim 1, wherein
wherein the first metal film and the third metal film mainly include one of metals of groups 6 to 8 of the periodic table and metals of groups 2 to 4 of the periodic table.

13. The semiconductor device according to claim 1, wherein
the second metal film is a TiN film, and each of the first and second gate insulating films is an HfON film.

14. The semiconductor device according to claim 13, wherein
the first MOS transistor includes an n type MOS transistor and the second MOS transistor includes a p type MOS transistor, and the TiN film includes Al.

15. The semiconductor device according to claim 13, wherein
the first MOS transistor includes a p type MOS transistor and the second MOS transistor includes an n type MOS transistor, the TiN film includes La, and the first and third metal films include Al.

16. A method of forming a semiconductor device, comprising:
forming a first metal film mainly including Ta on a gate insulating film in a region excluding an n MOS transistor formation region;
forming a polysilicon film to cover the gate insulating film and the first metal film;
forming a first dummy gate electrode by selectively etching the gate insulating film and the polysilicon film;
forming a second dummy gate electrode by selectively removing the gate insulating film, the first metal film and the polysilicon film;
forming an insulating layer to embed the first and second dummy gate electrodes and to expose upper surfaces of the first and second dummy gate electrodes;
removing the polysilicon film of the first and second dummy gate electrodes to form recesses in the insulating layer; and
forming a second metal film within the recesses and on the insulating layer.

17. The method according to claim 16, wherein
the gate insulating film is provided on a flat surface of a semiconductor substrate at least extending through from the n MOS transistor formation region to a p MOS transistor formation region.

18. The method according to claim 16, wherein
the gate insulating film has a substantially uniform thickness.
